(19) United States
(12) Patent Application Publication
(10) Pub. No.: US 2023/0291220 A1
(43) Pub. Date: Sep. 14, 2023

(54) ELECTRONIC CIRCUIT WITH HYBRID POWER SOURCES

(71) Applicant: Intel Corporation, Santa Clara, CA (US)

(72) Inventors: Yi How OOI, Bayan Lepas (MY); Chuen Ming TAN, Bayan Lepas (MY); Tai Loong WONG, Batu Maung (MY); Wei Cheang LAU, Bayan Lepas (MY); Sze Geat PANG, Gelugor (MY)

(21) Appl. No.: 17/694,071

(22) Filed: Mar. 14, 2022

(51) Int. Cl. H02J 7/00; H03K 17/687

(52) U.S. Cl. CPC H02J 7/007; H03K 17/6871

(57) ABSTRACT

Embodiments herein relate to an electronic circuit with a first port for providing a first power signal and a second port for providing a second power signal. Each of the ports may be coupled with a respective system gate and charging gate. A system gate may selectively couple a port with a system load, while the charging gate may selectively couple a port with a battery. Other embodiments may be described and/or claimed.

### FIELD

The present application generally relates to the field of electronic circuits and, more specifically, to an electronic circuit with hybrid power sources and associated apparatuses, systems, and methods.

### BACKGROUND

In current mobile platforms, the wall adapter of the platform may plug in to a Narrow Voltage Direct Charging (NVDC) stage on the platform. This first stage in power conversion may provide power to both charge the battery and operate the system. This dual-provision of power may require the charger to support higher loading and incur more power losses. Although charger power losses may not significantly impact battery life, the heat generated during charging may use up available thermal budget in the location of the charger. This may lead to difficulty in managing the heat of the overall system, and reduce the thermal budget that may be used for other tasks such as improving processor performance.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates an example power circuit with hybrid power sources, in accordance with various embodiments.

FIG. 2 illustrates an example of power flow in the power circuit of FIG. 1, in accordance with various embodiments.

FIG. 3 illustrates an alternative example of power flow in the power circuit of FIG. 1, in accordance with various embodiments.

FIG. 4 illustrates an alternative example of power flow in the power circuit of FIG. 1, in accordance with various embodiments.

FIG. 5 illustrates an alternative example power circuit with hybrid power sources, in accordance with various embodiments.

FIG. 6 illustrates a smart device or a computer system or a System-on-Chip (SoC) with apparatus and/or software for analysis or correction of duty-cycle issues, in accordance with some embodiments.

### DETAILED DESCRIPTION

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

Embodiments herein describe a circuit with respect to different gates, and use the terms activated/deactivated and opened/closed. As used herein, the term “closed” may be viewed as aligned with the term “activated,” and refer to a configuration wherein an electronic signal is allowed to pass from one side of the gate to the other. Conversely, as used herein, the term “opened” may be viewed as aligned with the term “deactivated,” and refer to a configuration wherein an electronic signal is prohibited from passing from one side of the gate to the other.

As previously noted, in current mobile platforms, the wall adapter of the platform may plug in to an NVDC stage on the platform. This first stage in power conversion may provide power to both charge the battery and operate the system. This dual-provision of power may require the charger to support higher loading and incur more power losses. Although charger power losses may not significantly impact battery life, the heat generated during charging may use up available thermal budget in the location of the charger. This may lead to difficulty in managing the heat of the overall system, and reduce the thermal budget that may be used for other tasks such as improving processor performance.

Embodiments herein may resolve one or issues related to the above-described thermal budget issue. Specifically, embodiments may enable two or more power sources to be used by the system. The power sources may be, for example, some combination of one or more universal serial bus (USB) power delivery (PD) sources, one or more alternating current (AC) power sources, and/or some other type of power source. Specifically, embodiments may include two or more ports, and a different power source may be connected to respective ones of the two or more ports. The connection between the ports, the system load, and the battery may be controlled by one or more gates.

Embodiments may further provide an increased thermal density for an NVDC charger. Specifically, embodiments may allow for the use of multiple ports without introducing a new charger.

More specifically, embodiments may allow for processor power optimization. That is, a power limit number of the processor may be increased over legacy charging circuits, while the circuit still charges a battery of the system. This increase may be due to extra power availability from the multiple power sources. This extra power availability may increase overall system performance, while also allowing for lower heat density (and therefore a higher thermal budget for the processor).

Embodiments may additionally or alternatively allow for full utilization of extended power range (EPR) of the system, which may allow a power supplied on a port to the system from, for example, a USB type-C(USB-C) device, to power up to 48 Volt (V) and/or 240 Watt (W) systems. In some embodiments, embodiments may further boost the power capability beyond 240 W.

Embodiments may additionally or alternatively allow for fast battery charging due to extra power availability. Such charging may be due to reduced power limitations that may have been the result of power sharing between the system and the battery in legacy systems.

Embodiments may additionally or alternatively allow for continuous charging while the system is in a high-use (e.g., “turbo”) mode. Specifically, the system may be able to fully utilize power from a port without the need to share that power with a charging battery.

Embodiments may additionally or alternatively allow for reduced cost by not requiring the use of an additional charging circuit to accommodate the power provided by two ports. For example, the addition of a charging circuit may increase cost by up to 50%, which may be undesirable.

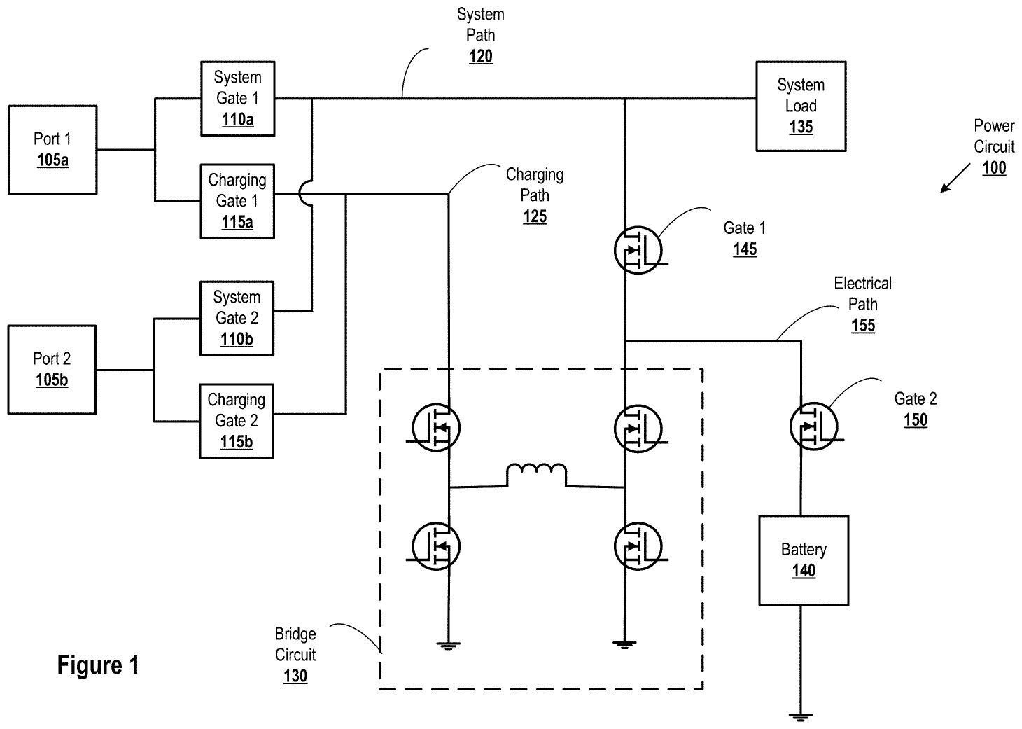

FIG. 1 illustrates an example power circuit 100 with hybrid power sources, in accordance with various embodiments. Specifically, the power circuit 100 may include two or more ports such as ports 105a and 105b (collectively, ports 105). Respective ones of the ports 105 may be coupled with one or more power sources (not shown in FIG. 1). The power sources may include, for example, a USB device such as a USB PD device, a USB-C device, or some other USB device that is configured to provide a power signal to one of the ports 105. Additionally or alternatively, the power sources may include another power source such as an AC power source, a direct current (DC) power source, or some other type of power source that is configured to provide a power signal to the power circuit 100. The use of different power sources may be referred to a circuit with “hybrid” power sources. However, it will be understood that in some embodiments the power sources coupled with port 105a may be of a same type as the power source coupled with port 105b (e.g., non-hybrid).

The ports 105 may be respectively coupled with a system gate 110a/110b (collectively, “system gates 110) and charging gates 115a/115b (collectively, “charging gates 115a”). In some embodiments, one or more of the system gates 110 and charging gates 115 may be a transistor such as a field effect transistor (FET). In other embodiments, one or more of the system gates 110 and charging gates 115 may be a different type of gate such as a switch, a hardware/software/firmware-controlled element, etc. The type of element or logic used for one of the gates of the system gates 110 and charging gates 115 may be dependent on factors such as budgetary constraints (e.g., a FET may be cheaper than a complicated digital logic circuit), thermal budget, etc.

Generally, the system gates 110 and charging gates 115 may be elements that are configured to be selectively activated to let a power signal move from one of the ports 105 to another part of the power circuit 100, or to be selectively deactivated to prevent a power signal from moving from one of the ports 105 to another part of the power circuit 100. In some embodiments, the system gates 110 and charging gates 115 may be coupled with a logic such as a processor, a processor core, or some other logic that is configured to analyze the power signal and identify whether respective ones of the system gates 110 and charging gates 115 should be opened or closed, as described below. In some embodiments, the same logic may be coupled with two or more of the system gates 110 and charging gates 115, while in other embodiments each of the system gates 110 and charging gates 115 may be controlled by an individual logic. Such logic is not shown in FIG. 1 for the sake of clarity and conciseness of the Figure.

The system gates 110 may be electrically coupled with a system path 120 (which may also be referred to as a “bypass” path or a “Vsys” path) that is electrically coupled with system load 135. The system load may be an electrical element of the system that requires a power signal. Such an element may be, for example, a processor, a memory, a fan, a port, or some other electrical element. As may be seen in FIG. 1, if a power signal is received on port 105a, and system gate 110a is closed, then the power signal may be provided along system path 120 to system load 135. Similarly, if a power signal is received on port 105b, and system gate 110b is closed, then the power signal may be provided along system path 120 to system load 135.

The charging gates 115 may be electrically coupled with a charging path 125 (which may also be referred to as a “NVDC charger” path) that is electrically coupled with a battery 140 of the system. The battery 140 may be, for example, a lithium-ion battery or some other battery of the electrical system. In some embodiments, a bridge circuit 130 may be electrically positioned between the charging gates 115 and the battery 140, as shown. The bridge circuit 130 may be serve a dual purpose. Specifically, the bridge circuit 130 may assist with shaping the power signal provided by one or both of the ports 105 (e.g., through “smoothing” the signal if the signal is an AC signal, etc.) Additionally or alternatively, the bridge circuit 130 may be referred to as a “charging” circuit that is coupled with the battery 140 as shown, and may be used to charge the battery 140.

In some embodiments, the bridge circuit 130 may be referred to as a “buck-boost regulator.” Specifically, dependent on how the bridge circuit 130 is configured or controlled, the bridge circuit 130 may regulate the voltage at the charging path 125 and/or the electrical path 155. For example, the bridge circuit 130 may be configured to have an “input side” and an “output side.” If the charging path 125 is at the input side of the bridge circuit 130, then the electrical path 155 is at the output side of the bridge circuit 130 (and vice-versa). The bridge circuit 130 may be configured to regulate the voltage at the output side to be higher or lower than the voltage at the input side.

As may be seen in FIG. 1, if a power signal is received on port 105a, and charging gate 115a is closed, then the power signal may be provided along charging path 125, through the bridge circuit 130, and to the battery 140. Similarly, if a power signal is received on port 105b, and charging gate 115b is closed, then the power signal may be provided along charging path 125, through the bridge circuit 130, and to the battery 140.

As may be seen, the battery 140 and system load 135 may be coupled with the bridge circuit 130 by an electrical path 155 that also electrically couples the battery 140 to the system load 135. More specifically, the bridge circuit 130 is coupled with the electrical path 155 at a point that is electrically between the battery 140 and the system load 135.

The electrical path 155 may include additional gates 145 and 150 as shown. Gate 145 may be electrically positioned between the bridge circuit 130 and the system load 135, and gate 150 may be positioned between the bridge circuit 130 and the battery 140. Similar to system gates 110 and charging gates 115, the gates 145 and 150 may, in some embodiments (and, as is illustrated) be FETs. In other embodiments, one or both of gates 145 and 150 may be some other type of gate or switch element. More generally, the gates 145 and 150 may be configured to be selectively activated or deactivated by one or more logic elements to allow (if activated) or prevent (if deactivated) a signal to flow through the gates 145 and 150.

As may be seen the gate 145 may control whether power can pass from the bridge circuit 130 and/or the battery 140 to the system load, as will be explained in greater detail below. The gate 150 may additionally control power flow from the battery 140 to the system load 135. In addition, the gate 150 may be used to enable or disable charging of the battery 140 if power is supplied to the bridge circuit 130. Specifically, if the gate 150 is deactivated, and power is supplied along the charging path 125 to the bridge circuit 130, the battery 140 may not charge. However, if the gate 150 is activated, and power is supplied along the charging path 125 to the bridge circuit 130, then the battery 140 may charge.

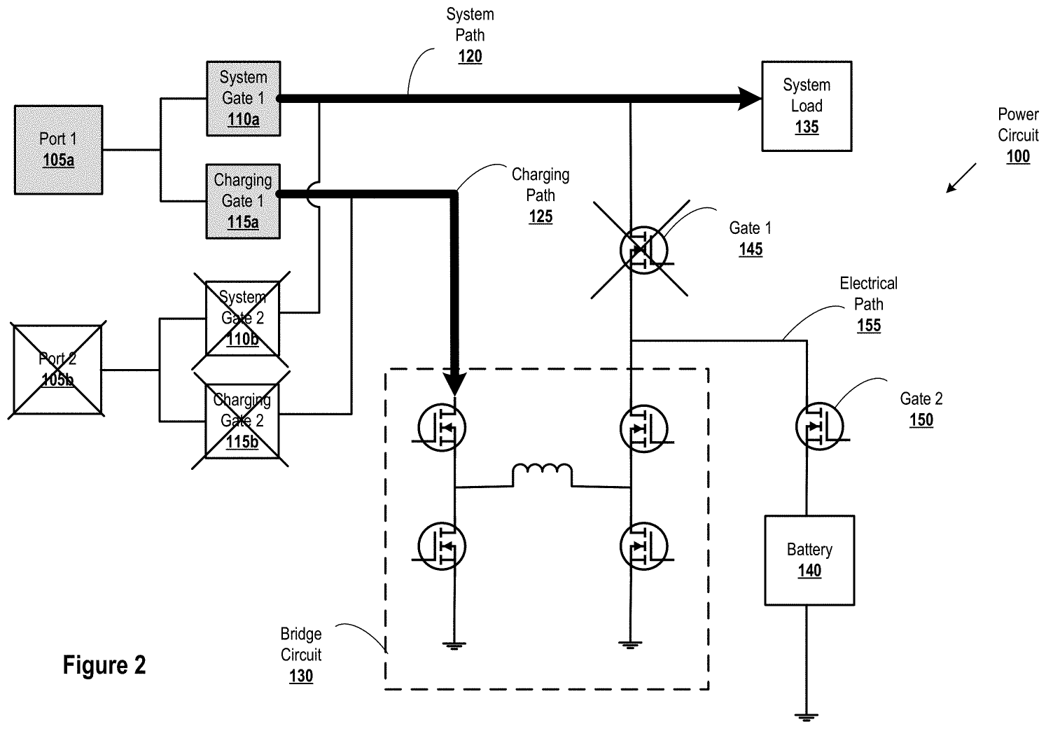

FIGS. 2-4 depict examples of power flow through the power circuit 100 of FIG. 1, dependent on different power signal combinations received from the ports 105. Specifically, in FIG. 2, a power signal may be received on port 105a, while no power signal is received on port 105b. As a result, in some embodiments both system gate 110a and charging gate 115 may be activated (i.e., “closed”) while system gate 110b and charging gate 115b are deactivated (i.e., “opened”). In some embodiments, it may be desirable to deactivate the gates 110b and 115b to prevent the port 105b from shorting with the port 105a.

In this embodiment, if gate 145 is closed and gate 150 is opened, then power may be supplied to the system load 135 along both the system path 120 and the charging path 125. Alternatively, if gate 145 is opened and gate 150 is closed, then power may be supplied to the system load 135 along the system path 120, while the battery 140 is charged based on power provided from the charging gate 115a along the charging path 125. It will be noted, for the sake of completeness, that if no power signal is received from either of the ports 105, and gates 145 and 150 are closed, then the battery 140 may be operable to provide power to the system load 135. In the embodiment is shown in FIG. 2, the gate 145 is deactivated while gate 150 is activated. As such, the power signal supplied by port 105a may be supplied to system load 135 and also used to charge the battery 140.

It will be understood that, in some embodiments, the power signal provided by the port 105a may not be sufficient to provide two concurrent power signals along the system path 120 and the charging path 125. In this situation (which is not explicitly shown in FIG. 2), the system gate 110a may be activated, and charging gate 115a may be deactivated. As a result, the power supplied by port 105a may be provided directly to the system load 135 along the system path 120 without occurring losses related to power conversion that may be a result of propagation through the bridge circuit 130.

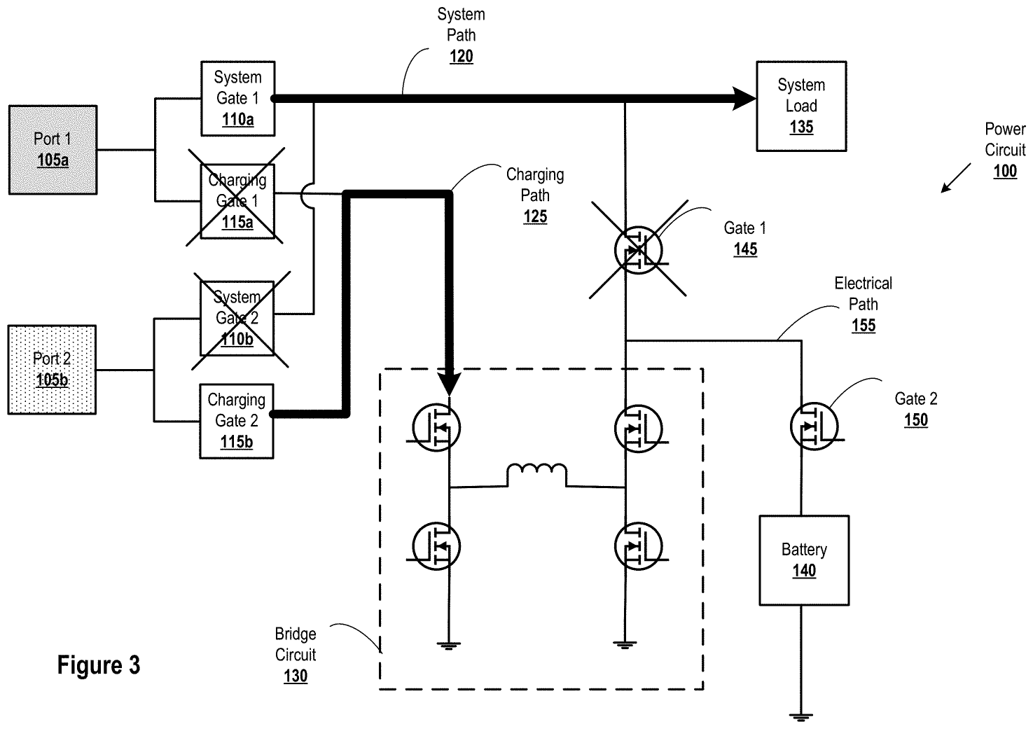

In FIG. 3, a first power signal may be received at port 105a, and a second power signal may be received at port 105b. In this embodiment, it may be identified that the power signal received at port 105a is greater than the power signal received at port 105b. As a result system gate 110a and charging gate 115b may be activated, while charging gate 115a and system gate 110b are deactivated to prevent shorting. As previously described, such determination, activation, or deactivation may be performed by one or more logic elements that are coupled with one or more of the ports 105, system gates 110, and charging gates 115. Additionally, as shown, gate 145 is deactivated and gate 150 is activated. In this embodiment, the (relatively higher) power signal provided by the port 105a may be provided along system path 120 to system load 135. At least partially concurrently, the (relatively lower) power signal provided by the port 105b may be provided along charging path 125 and used to charge the battery 140.

It will be noted that, although not shown, in some embodiments if it is identified that the battery 140 is at full charge or some other situation is present where full charging of the battery 140 is not desired, then the port 105b may be used to supplement the power of the system path 120. Specifically, gate 150 may be deactivated and gate 145 may be activated to electrically couple the output of the bridge circuit 130 to the system path 120. In this situation, the bridge circuit 130 may shape the power signal received on port 105b to be close to the voltage of the power signal on the system path 120, thereby shorting the charging path 125 and the system path 120 at the electrical path 155 (and through gate 145). Specifically, the bridge circuit 130 may shape the power signal output on the electrical path 155 to have a voltage slightly below the voltage of the system path 120 such that the output of the bridge circuit 130 can supplement the system path 120 when there is an increased power requirement at the system load 135.

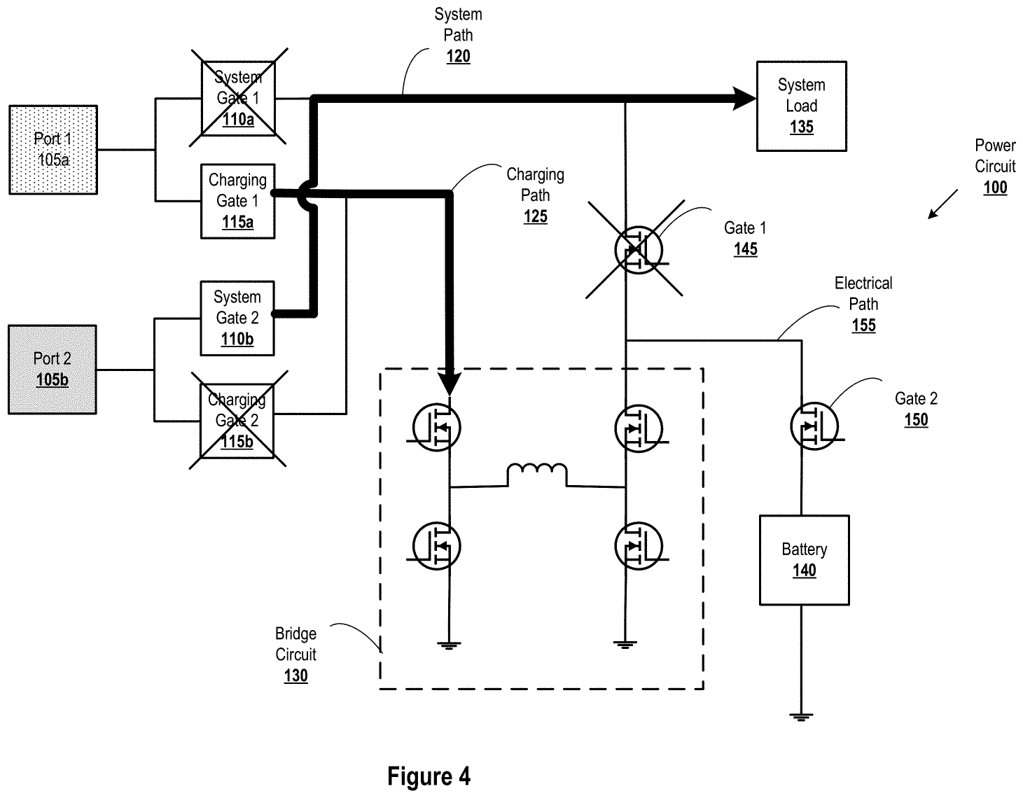

FIG. 4 depicts a situation similar to that of FIG. 3 wherein a first power signal may be received at port 105a, and a second power signal may be received at port 105b. In this embodiment, it may be identified that the power signal received at port 105a is less than the power signal received at port 105b. As a result system gate 110b and charging gate 115a may be activated, while charging gate 115b and system gate 110a are deactivated to prevent shorting. As previously described, such determination, activation, or deactivation may be performed by one or more logic elements that are coupled with one or more of the ports 105, system gates 110, and charging gates 115. Additionally, as shown, gate 145 is deactivated and gate 150 is activated. In this embodiment, the (relatively higher) power signal provided by the port 105b may be provided along system path 120 to system load 135. At least partially concurrently, the (relatively lower) power signal provided by the port 105a may be provided along charging path 125 and used to charge the battery 140. It will be understood that actions related to identifying that it is not desired to charge the battery 140, as described above, may similarly apply to the situation of FIG. 4.

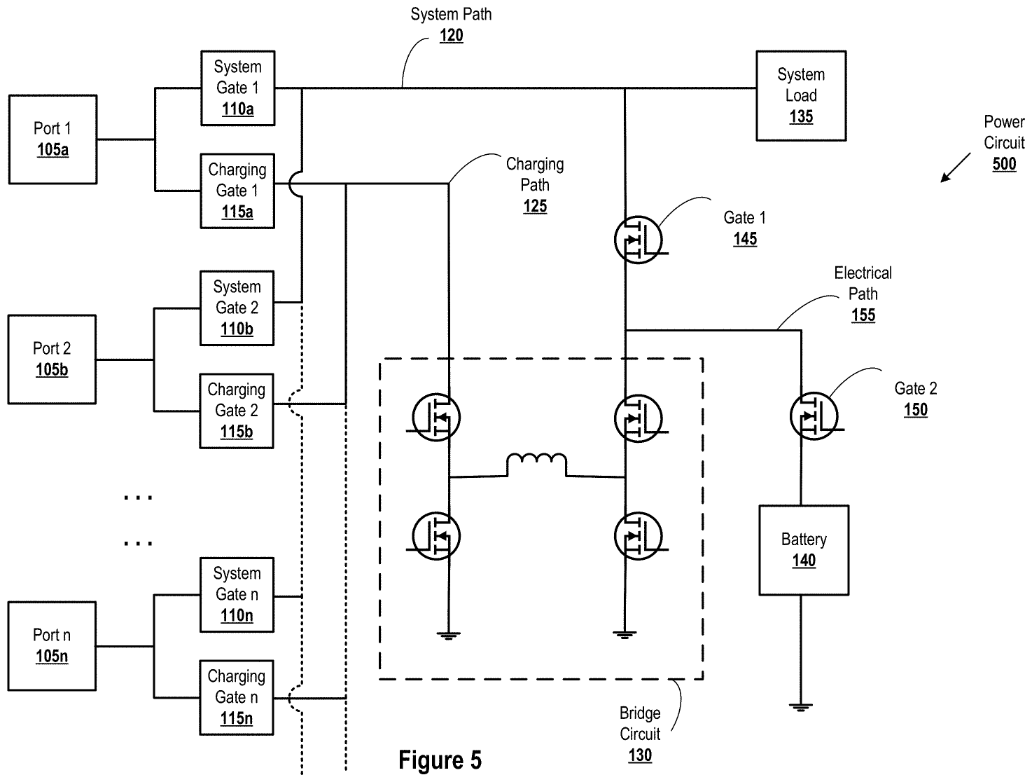

It will be understood that, even though the power circuit 100 is described as only having two ports 105, in other embodiments a power circuit may have additional ports. FIG. 5 illustrates an alternative example power circuit 500 with hybrid power sources, in accordance with various embodiments. Specifically, the power circuit 500 may include elements similar to those of power circuit 100, however the power circuit 500 may include one or more additional port(s), system gate(s), and charging gate(s). Specifically, in the power circuit 500, n (where n is greater than or equal to 3) ports, system gates, and charging gates may be present as indicated by port 105n, system gate 110n, and charging gate 115n. An example of how such ports and gates may be electrically coupled with other elements of the power circuit 500 are depicted in FIG. 5.

As noted, embodiments herein may provide benefits in terms of charging time, cost savings, etc. For example, by using only a single bridge circuit, the embodiments herein may be on the order of 33% cheaper than an architecture that includes two bridge circuits. Embodiments herein may also be approximately 45% smaller than a dual-bridge circuit architecture. Additionally, embodiments may provide battery charging at least twice as fast as an architecture that allows for only a single power source. Other benefits may be present in other embodiments.

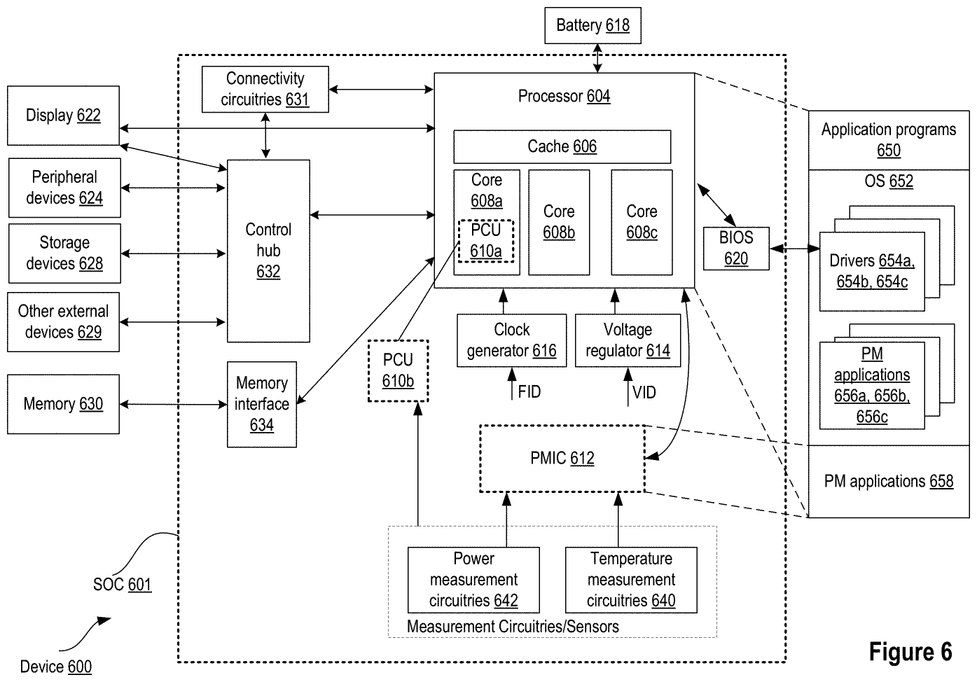

FIG. 6 illustrates a smart device or a computer system or a System-on-Chip (SoC) with apparatus and/or software for analysis or correction of duty-cycle issues, in accordance with some embodiments.

In some embodiments, device 600 represents an appropriate computing device, such as a computing tablet, a mobile phone or smart-phone, a laptop, a desktop, an Internet-of-Things (IOT) device, a server, a wearable device, a set-top box, a wireless-enabled e-reader, or the like. It will be understood that certain components are shown generally, and not all components of such a device are shown in device 600. The apparatus and/or software for controlling wake sources in a system to reduce power consumption in sleep state can be in the wireless connectivity circuitries 631, PCU 610, and/or other logic blocks (e.g., operating system 652) that can manage power for the computer system.

In an example, the device 600 comprises an SoC (System-on-Chip) 601. An example boundary of the SoC 601 is illustrated using dotted lines in FIG. 6, with some example components being illustrated to be included within SoC 601—however, SoC 601 may include any appropriate components of device 600.

In some embodiments, device 600 includes processor 604. Processor 604 can include one or more physical devices, such as microprocessors, application processors, microcontrollers, programmable logic devices, processing cores, or other processing means. The processing operations performed by processor 604 include the execution of an operating platform or operating system on which applications and/or device functions are executed. The processing operations include operations related to I/O (input/output) with a human user or with other devices, operations related to power management, operations related to connecting computing device 600 to another device, and/or the like. The processing operations may also include operations related to audio I/O and/or display I/O.

In some embodiments, processor 604 includes multiple processing cores (also referred to as cores) 608a, 608b, 608c. Although merely three cores 608a, 608b, 608c are illustrated in FIG. 6, processor 604 may include any other appropriate number of processing cores, e.g., tens, or even hundreds of processing cores. Processor cores 608a, 608b, 608c may be implemented on a single integrated circuit (IC) chip. Moreover, the chip may include one or more shared and/or private caches, buses or interconnections, graphics and/or memory controllers, or other components.

In some embodiments, processor 604 includes cache 606. In an example, sections of cache 606 may be dedicated to individual cores 608 (e.g., a first section of cache 606 dedicated to core 608a, a second section of cache 606 dedicated to core 608b, and so on). In an example, one or more sections of cache 606 may be shared among two or more of cores 608. Cache 606 may be split in different levels, e.g., level 1 (L1) cache, level 2 (L2) cache, level 3 (L3) cache, etc.

In some embodiments, processor core 604 may include a fetch unit to fetch instructions (including instructions with conditional branches) for execution by the core 604. The instructions may be fetched from any storage devices such as the memory 630. Processor core 604 may also include a decode unit to decode the fetched instruction. For example, the decode unit may decode the fetched instruction into a plurality of micro-operations. Processor core 604 may include a schedule unit to perform various operations associated with storing decoded instructions. For example, the schedule unit may hold data from the decode unit until the instructions are ready for dispatch, e.g., until all source values of a decoded instruction become available. In one embodiment, the schedule unit may schedule and/or issue (or dispatch) decoded instructions to an execution unit for execution.

The execution unit may execute the dispatched instructions after they are decoded (e.g., by the decode unit) and dispatched (e.g., by the schedule unit). In an embodiment, the execution unit may include more than one execution unit (such as an imaging computational unit, a graphics computational unit, a general-purpose computational unit, etc.). The execution unit may also perform various arithmetic operations such as addition, subtraction, multiplication, and/or division, and may include one or more an arithmetic logic units (ALUs). In an embodiment, a co-processor (not shown) may perform various arithmetic operations in conjunction with the execution unit.

Further, execution unit may execute instructions out-of-order. Hence, processor core 604 may be an out-of-order processor core in one embodiment. Processor core 604 may also include a retirement unit. The retirement unit may retire executed instructions after they are committed. In an embodiment, retirement of the executed instructions may result in processor state being committed from the execution of the instructions, physical registers used by the instructions being de-allocated, etc. Processor core 604 may also include a bus unit to enable communication between components of processor core 604 and other components via one or more buses. Processor core 604 may also include one or more registers to store data accessed by various components of the core 604 (such as values related to assigned app priorities and/or sub-system states (modes) association.

In some embodiments, device 600 comprises connectivity circuitries 631. For example, connectivity circuitries 631 includes hardware devices (e.g., wireless and/or wired connectors and communication hardware) and/or software components (e.g., drivers, protocol stacks), e.g., to enable device 600 to communicate with external devices. Device 600 may be separate from the external devices, such as other computing devices, wireless access points or base stations, etc.

In an example, connectivity circuitries 631 may include multiple different types of connectivity. To generalize, the connectivity circuitries 631 may include cellular connectivity circuitries, wireless connectivity circuitries, etc. Cellular connectivity circuitries of connectivity circuitries 631 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, 3rd Generation Partnership Project (3GPP) Universal Mobile Telecommunications Systems (UMTS) system or variations or derivatives, 3GPP Long-Term Evolution (LTE) system or variations or derivatives, 3GPP LTE-Advanced (LTE-A) system or variations or derivatives, Fifth Generation (5G) wireless system or variations or derivatives, 5G mobile networks system or variations or derivatives, 5G New Radio (NR) system or variations or derivatives, or other cellular service standards. Wireless connectivity circuitries (or wireless interface) of the connectivity circuitries 631 refers to wireless connectivity that is not cellular, and can include personal area networks (such as Bluetooth, Near Field, etc.), local area networks (such as Wi-Fi), and/or wide area networks (such as WiMax), and/or other wireless communication. In an example, connectivity circuitries 631 may include a network interface, such as a wired or wireless interface, e.g., so that a system embodiment may be incorporated into a wireless device, for example, a cell phone or personal digital assistant.

In some embodiments, device 600 comprises control hub 632, which represents hardware devices and/or software components related to interaction with one or more I/O devices. For example, processor 604 may communicate with one or more of display 622, one or more peripheral devices 624, storage devices 628, one or more other external devices 629, etc., via control hub 632. Control hub 632 may be a chipset, a Platform Control Hub (PCH), and/or the like.

For example, control hub 632 illustrates one or more connection points for additional devices that connect to device 600, e.g., through which a user might interact with the system. For example, devices (e.g., devices 629) that can be attached to device 600 include microphone devices, speaker or stereo systems, audio devices, video systems or other display devices, keyboard or keypad devices, or other I/O devices for use with specific applications such as card readers or other devices.

As mentioned above, control hub 632 can interact with audio devices, display 622, etc. For example, input through a microphone or other audio device can provide input or commands for one or more applications or functions of device 600. Additionally, audio output can be provided instead of, or in addition to display output. In another example, if display 622 includes a touch screen, display 622 also acts as an input device, which can be at least partially managed by control hub 632. There can also be additional buttons or switches on computing device 600 to provide I/O functions managed by control hub 632. In one embodiment, control hub 632 manages devices such as accelerometers, cameras, light sensors or other environmental sensors, or other hardware that can be included in device 600. The input can be part of direct user interaction, as well as providing environmental input to the system to influence its operations (such as filtering for noise, adjusting displays for brightness detection, applying a flash for a camera, or other features).

In some embodiments, control hub 632 may couple to various devices using any appropriate communication protocol, e.g., PCIe (Peripheral Component Interconnect Express), USB (Universal Serial Bus), Thunderbolt, High Definition Multimedia Interface (HDMI), Firewire, etc.

In some embodiments, display 622 represents hardware (e.g., display devices) and software (e.g., drivers) components that provide a visual and/or tactile display for a user to interact with device 600. Display 622 may include a display interface, a display screen, and/or hardware device used to provide a display to a user. In some embodiments, display 622 includes a touch screen (or touch pad) device that provides both output and input to a user. In an example, display 622 may communicate directly with the processor 604. Display 622 can be one or more of an internal display device, as in a mobile electronic device or a laptop device or an external display device attached via a display interface (e.g., DisplayPort, etc.). In one embodiment display 622 can be a head mounted display (HMD) such as a stereoscopic display device for use in virtual reality (VR) applications or augmented reality (AR) applications.

In some embodiments, and although not illustrated in the Figure, in addition to (or instead of) processor 604, device 600 may include Graphics Processing Unit (GPU) comprising one or more graphics processing cores, which may control one or more aspects of displaying contents on display 622.

Control hub 632 (or platform controller hub) may include hardware interfaces and connectors, as well as software components (e.g., drivers, protocol stacks) to make peripheral connections, e.g., to peripheral devices 624.

It will be understood that device 600 could both be a peripheral device to other computing devices, as well as have peripheral devices connected to it. Device 600 may have a “docking” connector to connect to other computing devices for purposes such as managing (e.g., downloading and/or uploading, changing, synchronizing) content on device 600. Additionally, a docking connector can allow device 600 to connect to certain peripherals that allow computing device 600 to control content output, for example, to audiovisual or other systems.

In addition to a proprietary docking connector or other proprietary connection hardware, device 600 can make peripheral connections via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

In some embodiments, connectivity circuitries 631 may be coupled to control hub 632, e.g., in addition to, or instead of, being coupled directly to the processor 604. In some embodiments, display 622 may be coupled to control hub 632, e.g., in addition to, or instead of, being coupled directly to processor 604.

In some embodiments, device 600 comprises memory 630 coupled to processor 604 via memory interface 634. Memory 630 includes memory devices for storing information in device 600.

In some embodiments, memory 630 includes apparatus to maintain stable clocking as described with reference to various embodiments. Memory can include nonvolatile (state does not change if power to the memory device is interrupted) and/or volatile (state is indeterminate if power to the memory device is interrupted) memory devices. Memory device 630 can be a dynamic random-access memory (DRAM) device, a static random-access memory (SRAM) device, flash memory device, phase-change memory device, or some other memory device having suitable performance to serve as process memory. In one embodiment, memory 630 can operate as system memory for device 600, to store data and instructions for use when the one or more processors 604 executes an application or process. Memory 630 can store application data, user data, music, photos, documents, or other data, as well as system data (whether long-term or temporary) related to the execution of the applications and functions of device 600.

Elements of various embodiments and examples are also provided as a machine-readable medium (e.g., memory 630) for storing the computer-executable instructions (e.g., instructions to implement any other processes discussed herein). The machine-readable medium (e.g., memory 630) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, device 600 comprises temperature measurement circuitries 640, e.g., for measuring temperature of various components of device 600. In an example, temperature measurement circuitries 640 may be embedded, or coupled or attached to various components, whose temperature are to be measured and monitored. For example, temperature measurement circuitries 640 may measure temperature of (or within) one or more of cores 608a, 608b, 608c, voltage regulator 614, memory 630, a mother-board of SoC 601, and/or any appropriate component of device 600.

In some embodiments, device 600 comprises power measurement circuitries 642, e.g., for measuring power consumed by one or more components of the device 600. In an example, in addition to, or instead of, measuring power, the power measurement circuitries 642 may measure voltage and/or current. In an example, the power measurement circuitries 642 may be embedded, or coupled or attached to various components, whose power, voltage, and/or current consumption are to be measured and monitored. For example, power measurement circuitries 642 may measure power, current and/or voltage supplied by one or more voltage regulators 614, power supplied to SoC 601, power supplied to device 600, power consumed by processor 604 (or any other component) of device 600, etc.

In some embodiments, device 600 comprises one or more voltage regulator circuitries, generally referred to as voltage regulator (VR) 614. VR 614 generates signals at appropriate voltage levels, which may be supplied to operate any appropriate components of the device 600. Merely as an example, VR 614 is illustrated to be supplying signals to processor 604 of device 600. In some embodiments, VR 614 receives one or more Voltage Identification (VID) signals, and generates the voltage signal at an appropriate level, based on the VID signals. Various type of VRs may be utilized for the VR 614. For example, VR 614 may include a “buck” VR, “boost” VR, a combination of buck and boost VRs, low dropout (LDO) regulators, switching DC-DC regulators, constant-on-time controller-based DC-DC regulator, etc. Buck VR is generally used in power delivery applications in which an input voltage needs to be transformed to an output voltage in a ratio that is smaller than unity. Boost VR is generally used in power delivery applications in which an input voltage needs to be transformed to an output voltage in a ratio that is larger than unity. In some embodiments, each processor core has its own VR, which is controlled by PCU 610a/b and/or PMIC 612. In some embodiments, each core has a network of distributed LDOs to provide efficient control for power management. The LDOs can be digital, analog, or a combination of digital or analog LDOs. In some embodiments, VR 614 includes current tracking apparatus to measure current through power supply rail(s).

In some embodiments, device 600 comprises one or more clock generator circuitries, generally referred to as clock generator 616. Clock generator 616 generates clock signals at appropriate frequency levels, which may be supplied to any appropriate components of device 600. Merely as an example, clock generator 616 is illustrated to be supplying clock signals to processor 604 of device 600. In some embodiments, clock generator 616 receives one or more Frequency Identification (FID) signals, and generates the clock signals at an appropriate frequency, based on the FID signals.

In some embodiments, device 600 comprises battery 618 (which may be similar to battery 140) supplying power to various components of device 600. Such components may be, for example, an element of system load 135. Merely as an example, battery 618 is illustrated to be supplying power to processor 604. Although not illustrated in the Figures, device 600 may comprise a charging circuitry (e.g., the charging circuitry of one of FIGS. 1-5), e.g., to recharge the battery, based on Alternating Current (AC) power supply received from an AC adapter.

In some embodiments, device 600 comprises Power Control Unit (PCU) 610 (also referred to as Power Management Unit (PMU), Power Controller, etc.). In an example, some sections of PCU 610 may be implemented by one or more processing cores 608, and these sections of PCU 610 are symbolically illustrated using a dotted box and labelled PCU 610a. In an example, some other sections of PCU 610 may be implemented outside the processing cores 608, and these sections of PCU 610 are symbolically illustrated using a dotted box and labelled as PCU 610b. PCU 610 may implement various power management operations for device 600. PCU 610 may include hardware interfaces, hardware circuitries, connectors, registers, etc., as well as software components (e.g., drivers, protocol stacks), to implement various power management operations for device 600. For example, the PCU 610 may control operation of one or more of gates 110, 115, 145, and/or 150.

In some embodiments, device 600 comprises Power Management Integrated Circuit (PMIC) 612, e.g., to implement various power management operations for device 600. In some embodiments, PMIC 612 is a Reconfigurable Power Management ICs (RPMICs) and/or an IMVP (Intel® Mobile Voltage Positioning). In an example, the PMIC is within an IC chip separate from processor 604. The may implement various power management operations for device 600. PMIC 612 may include hardware interfaces, hardware circuitries, connectors, registers, etc., as well as software components (e.g., drivers, protocol stacks), to implement various power management operations for device 600.

In an example, device 600 comprises one or both PCU 610 or PMIC 612. In an example, any one of PCU 610 or PMIC 612 may be absent in device 600, and hence, these components are illustrated using dotted lines.

Various power management operations of device 600 may be performed by PCU 610, by PMIC 612, or by a combination of PCU 610 and PMIC 612. For example, PCU 610 and/or PMIC 612 may select a power state (e.g., P-state) for various components of device 600. For example, PCU 610 and/or PMIC 612 may select a power state (e.g., in accordance with the ACPI (Advanced Configuration and Power Interface) specification) for various components of device 600. Merely as an example, PCU 610 and/or PMIC 612 may cause various components of the device 600 to transition to a sleep state, to an active state, to an appropriate C state (e.g., CO state, or another appropriate C state, in accordance with the ACPI specification), etc. In an example, PCU 610 and/or PMIC 612 may control a voltage output by VR 614 and/or a frequency of a clock signal output by the clock generator, e.g., by outputting the VID signal and/or the FID signal, respectively. In an example, PCU 610 and/or PMIC 612 may control battery power usage, charging of battery 618, and features related to power saving operation.

The clock generator 616 can comprise a phase locked loop (PLL), frequency locked loop (FLL), or any suitable clock source. In some embodiments, each core of processor 604 has its own clock source. As such, each core can operate at a frequency independent of the frequency of operation of the other core. In some embodiments, PCU 610 and/or PMIC 612 performs adaptive or dynamic frequency scaling or adjustment. For example, clock frequency of a processor core can be increased if the core is not operating at its maximum power consumption threshold or limit. In some embodiments, PCU 610 and/or PMIC 612 determines the operating condition of each core of a processor, and opportunistically adjusts frequency and/or power supply voltage of that core without the core clocking source (e.g., PLL of that core) losing lock when the PCU 610 and/or PMIC 612 determines that the core is operating below a target performance level. For example, if a core is drawing current from a power supply rail less than a total current allocated for that core or processor 604, then PCU 610 and/or PMIC 612 can temporality increase the power draw for that core or processor 604 (e.g., by increasing clock frequency and/or power supply voltage level) so that the core or processor 604 can perform at higher performance level. As such, voltage and/or frequency can be increased temporality for processor 604 without violating product reliability.

In an example, PCU 610 and/or PMIC 612 may perform power management operations, e.g., based at least in part on receiving measurements from power measurement circuitries 642, temperature measurement circuitries 640, charge level of battery 618, and/or any other appropriate information that may be used for power management. To that end, PMIC 612 is communicatively coupled to one or more sensors to sense/detect various values/variations in one or more factors having an effect on power/thermal behavior of the system/platform. Examples of the one or more factors include electrical current, voltage droop, temperature, operating frequency, operating voltage, power consumption, inter-core communication activity, etc. One or more of these sensors may be provided in physical proximity (and/or thermal contact/coupling) with one or more components or logic/IP blocks of a computing system. Additionally, sensor(s) may be directly coupled to PCU 610 and/or PMIC 612 in at least one embodiment to allow PCU 610 and/or PMIC 612 to manage processor core energy at least in part based on value(s) detected by one or more of the sensors.

Also illustrated is an example software stack of device 600 (although not all elements of the software stack are illustrated). Merely as an example, processors 604 may execute application programs 650, Operating System 652, one or more Power Management (PM) specific application programs (e.g., generically referred to as PM applications 658), and/or the like. PM applications 658 may also be executed by the PCU 610 and/or PMIC 612. OS 652 may also include one or more PM applications 656a, 656b, 656c. The OS 652 may also include various drivers 654a, 654b, 654c, etc., some of which may be specific for power management purposes. In some embodiments, device 600 may further comprise a Basic Input/output System (BIOS) 620. BIOS 620 may communicate with OS 652 (e.g., via one or more drivers 654), communicate with processors 604, etc.

For example, one or more of PM applications 658, 656, drivers 654, BIOS 620, etc. may be used to implement power management specific tasks, e.g., to control voltage and/or frequency of various components of device 600, to control wake-up state, sleep state, and/or any other appropriate power state of various components of device 600, control battery power usage, charging of the battery 618, features related to power saving operation, etc.

In some embodiments, battery 618 is a Li-metal battery with a pressure chamber to allow uniform pressure on a battery. The pressure chamber is supported by metal plates (such as pressure equalization plate) used to give uniform pressure to the battery. The pressure chamber may include pressured gas, elastic material, spring plate, etc. The outer skin of the pressure chamber is free to bow, restrained at its edges by (metal) skin, but still exerts a uniform pressure on the plate that is compressing the battery cell. The pressure chamber gives uniform pressure to battery, which is used to enable high-energy density battery with, for example, 20% more battery life.

In some embodiments, pCode executing on PCU 610a/b has a capability to enable extra compute and telemetries resources for the runtime support of the pCode. Here pCode refers to a firmware executed by PCU 610a/b to manage performance of the SoC 601. For example, pCode may set frequencies and appropriate voltages for the processor. Part of the pCode are accessible via OS 652. In various embodiments, mechanisms and methods are provided that dynamically change an Energy Performance Preference (EPP) value based on workloads, user behavior, and/or system conditions. There may be a well-defined interface between OS 652 and the pCode. The interface may allow or facilitate the software configuration of several parameters and/or may provide hints to the pCode. As an example, an EPP parameter may inform a pCode algorithm as to whether performance or battery life is more important.

This support may be done as well by the OS 652 by including machine-learning support as part of OS 652 and either tuning the EPP value that the OS hints to the hardware (e.g., various components of SoC 601) by machine-learning prediction, or by delivering the machine-learning prediction to the pCode in a manner similar to that done by a Dynamic Tuning Technology (DTT) driver. In this model, OS 652 may have visibility to the same set of telemetries as are available to a DTT. As a result of a DTT machine-learning hint setting, pCode may tune its internal algorithms to achieve optimal power and performance results following the machine-learning prediction of activation type. The pCode as example may increase the responsibility for the processor utilization change to enable fast response for user activity, or may increase the bias for energy saving either by reducing the responsibility for the processor utilization or by saving more power and increasing the performance lost by tuning the energy saving optimization. This approach may facilitate saving more battery life in case the types of activities enabled lose some performance level over what the system can enable. The pCode may include an algorithm for dynamic EPP that may take the two inputs, one from OS 652 and the other from software such as DTT, and may selectively choose to provide higher performance and/or responsiveness. As part of this method, the pCode may enable in the DTT an option to tune its reaction for the DTT for different types of activity.

Some non-limiting Examples of various embodiments are presented below.

Example 1 includes an electronic circuit comprising: a system load; a battery; a first port for providing a first power signal, wherein the first port is coupled with a first system gate and a first charging gate, wherein the first system gate is configured to be selectively activated to electrically couple the first port to the system load, and wherein the first charging gate is configured to be selectively activated to electrically couple the first port to the battery; and a second port for providing a second power signal, wherein the second port is coupled with a second system gate and a second charging gate, wherein the second system gate is configured to be selectively activated to electrically couple the second port to the system load, and wherein the second charging gate is configured to be selectively activated to electrically couple the second port to the battery.

Example 2 includes the electronic circuit of example 1, and/or some other example herein, wherein at least one of the first system gate, first charging gate, second system gate, and second charging gate are a field effect transistor (FET).

Example 3 includes the electronic circuit of any of examples 1-2, and/or some other example herein, wherein the first power signal is received from a universal serial bus (USB) device coupled with the first port.

Example 4 includes the electronic circuit of any of examples 1-3, and/or some other example herein, wherein the first port is configured to provide the first power signal at least partially concurrently with provision of the second power signal by the second port.

Example 5 includes the electronic circuit of any of examples 1-4, and/or some other example herein, further comprising a third port for providing a third power signal, wherein the third port is coupled with a third system gate and a third charging gate, wherein the third system gate is configured to be selectively activated to electrically couple the third port to the system load, and wherein the third charging gate is configured to be selectively activated to electrically couple the third port to the battery.

Example 6 includes the electronic circuit of any of examples 1-5, and/or some other example herein, wherein the first charging gate is activated and the second charging gate is deactivated if the first power signal is less than the second power signal.

Example 7 includes the electronic circuit of any of examples 1-6, and/or some other example herein, wherein the first system gate and the first charging gate are activated if the second port does not provide the second power signal.

Example 8 includes the electronic circuit of any of examples 1-7, and/or some other example herein, wherein the battery is electrically coupled with the system load by a first electrical path, and further comprising a bridge circuit in a second electrical path between the first electrical path and the first and second charging gates, wherein the bridge is electrically positioned between the first electrical path and the first and second charging gates.

Example 9 includes the electronic circuit of example 8, and/or some other example herein, further comprising: a first gate in the first electrical path and electrically positioned between the bridge circuit and the system load, wherein the first gate is configured to be selectively activated to electrically couple the bridge circuit to the system load; and a second gate in the first electrical path and electrically positioned between the bridge circuit and the battery, wherein the second gate is configured to be selectively activated to allow charging of the battery.

Example 10 includes the electronic circuit of example 9, and/or some other example herein, wherein if the first gate and the second gate are activated, the battery is electrically coupled with the system load.

Example 11 includes an electronic circuit comprising: a first port for providing a first power signal, wherein the first port is coupled with a first system gate and a first charging gate, wherein the first system gate is configured to be selectively activated to electrically couple the first port to a system load of a system of which the electronic circuit is a part, and wherein the first charging gate is configured to be selectively activated to electrically couple the first port to a battery of the system of which the electronic circuit is a part; and a second port for providing a second power signal, wherein the second port is coupled with a second system gate and a second charging gate, wherein the second system gate is configured to be selectively activated to electrically couple the second port to the system load, and wherein the second charging gate is configured to be selectively activated to electrically couple the second port to the battery.

Example 12 includes the electronic circuit of example 11, and/or some other example herein, wherein at least one of the first system gate, first charging gate, second system gate, and second charging gate are a field effect transistor (FET).

Example 13 includes the electronic circuit of any of examples 11-12, and/or some other example herein, wherein the first power signal is received from a universal serial bus (USB) device coupled with the first port.

Example 14 includes the electronic circuit of any of examples 11-13, and/or some other example herein, wherein the first port is configured to provide the first power signal at least partially concurrently with provision of the second power signal by the second port.

Example 15 includes the electronic circuit of any of examples 11-14, and/or some other example herein, further comprising a third port for providing a third power signal, wherein the third port is coupled with a third system gate and a third charging gate, wherein the third system gate is configured to be selectively activated to electrically couple the third port to the system load, and wherein the third charging gate is configured to be selectively activated to electrically couple the third port to the battery.

Example 16 includes the electronic circuit of any of examples 11-15, and/or some other example herein, wherein the first charging gate is activated and the second charging gate is deactivated if the first power signal is less than the second power signal.

Example 17 includes the electronic circuit of any of examples 11-16, and/or some other example herein, wherein the first system gate and the first charging gate are activated if the second port does not provide the second power signal.

Example 18 includes the electronic circuit of any of examples 11-17, and/or some other example herein, wherein the battery is electrically coupled with the system load by a first electrical path, and further comprising a bridge circuit in a second electrical path between the first electrical path and the first and second charging gates, wherein the bridge is electrically positioned between the first electrical path and the first and second charging gates.

Example 19 includes the electronic circuit of example 18, and/or some other example herein, further comprising: a first gate in the first electrical path and electrically positioned between the bridge circuit and the system load, wherein the first gate is configured to be selectively activated to electrically couple the bridge circuit to the system load; and a second gate in the first electrical path and electrically positioned between the bridge circuit and the battery, wherein the second gate is configured to be selectively activated to allow charging of the battery.

Example 20 includes the electronic circuit of example 19, and/or some other example herein, wherein if the first gate and the second gate are activated, the battery is electrically coupled with the system load.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1. An electronic circuit comprising:
a system load;
a battery;
a first port for providing a first power signal, wherein the first port is coupled with a first system gate and a first charging gate, wherein the first system gate is configured to be selectively activated to electrically couple the first port to the system load, and wherein the first charging gate is configured to be selectively activated to electrically couple the first port to the battery; and
a second port for providing a second power signal, wherein the second port is coupled with a second system gate and a second charging gate, wherein the second system gate is configured to be selectively activated to electrically couple the second port to the system load, and wherein the second charging gate is configured to be selectively activated to electrically couple the second port to the battery.

2. The electronic circuit of claim 1, wherein at least one of the first system gate, first charging gate, second system gate, and second charging gate are a field effect transistor (FET).

3. The electronic circuit of claim 1, wherein the first power signal is received from a universal serial bus (USB) device coupled with the first port.

4. The electronic circuit of claim 1, wherein the first port is configured to provide the first power signal at least partially concurrently with provision of the second power signal by the second port.

5. The electronic circuit of claim 1, further comprising a third port for providing a third power signal, wherein the third port is coupled with a third system gate and a third charging gate, wherein the third system gate is configured to be selectively activated to electrically couple the third port to the system load, and wherein the third charging gate is configured to be selectively activated to electrically couple the third port to the battery.

6. The electronic circuit of claim 1, wherein the first charging gate is activated and the second charging gate is deactivated if the first power signal is less than the second power signal.

7. The electronic circuit of claim 1, wherein the first system gate and the first charging gate are activated if the second port does not provide the second power signal.

8. The electronic circuit of claim 1, wherein the battery is electrically coupled with the system load by a first electrical path, and further comprising a bridge circuit in a second electrical path between the first electrical path and the first and second charging gates, wherein the bridge is electrically positioned between the first electrical path and the first and second charging gates.

9. The electronic circuit of claim 8, further comprising:
a first gate in the first electrical path and electrically positioned between the bridge circuit and the system load, wherein the first gate is configured to be selectively activated to electrically couple the bridge circuit to the system load; and
a second gate in the first electrical path and electrically positioned between the bridge circuit and the battery, wherein the second gate is configured to be selectively activated to allow charging of the battery.

10. The electronic circuit of claim 9, wherein if the first gate and the second gate are activated, the battery is electrically coupled with the system load.

11. An electronic circuit comprising:
a first port for providing a first power signal, wherein the first port is coupled with a first system gate and a first charging gate, wherein the first system gate is configured to be selectively activated to electrically couple the first port to a system load of a system of which the electronic circuit is a part, and wherein the first charging gate is configured to be selectively activated to electrically couple the first port to a battery of the system of which the electronic circuit is a part; and
a second port for providing a second power signal, wherein the second port is coupled with a second system gate and a second charging gate, wherein the second system gate is configured to be selectively activated to electrically couple the second port to the system load, and wherein the second charging gate is configured to be selectively activated to electrically couple the second port to the battery.

12. The electronic circuit of claim 11, wherein at least one of the first system gate, first charging gate, second system gate, and second charging gate are a field effect transistor (FET).

13. The electronic circuit of claim 11, wherein the first power signal is received from a universal serial bus (USB) device coupled with the first port.

14. The electronic circuit of claim 11, wherein the first port is configured to provide the first power signal at least partially concurrently with provision of the second power signal by the second port.

15. The electronic circuit of claim 11, further comprising a third port for providing a third power signal, wherein the third port is coupled with a third system gate and a third charging gate, wherein the third system gate is configured to be selectively activated to electrically couple the third port to the system load, and wherein the third charging gate is configured to be selectively activated to electrically couple the third port to the battery.

16. The electronic circuit of claim 11, wherein the first charging gate is activated and the second charging gate is deactivated if the first power signal is less than the second power signal.

17. The electronic circuit of claim 11, wherein the first system gate and the first charging gate are activated if the second port does not provide the second power signal.

18. The electronic circuit of claim 11, wherein the battery is electrically coupled with the system load by a first electrical path, and further comprising a bridge circuit in a second electrical path between the first electrical path and the first and second charging gates, wherein the bridge is electrically positioned between the first electrical path and the first and second charging gates.

19. The electronic circuit of claim 18, further comprising:
a first gate in the first electrical path and electrically positioned between the bridge circuit and the system load, wherein the first gate is configured to be selectively activated to electrically couple the bridge circuit to the system load; and
a second gate in the first electrical path and electrically positioned between the bridge circuit and the battery, wherein the second gate is configured to be selectively activated to allow charging of the battery.

20. The electronic circuit of claim 19, wherein if the first gate and the second gate are activated, the battery is electrically coupled with the system load.
